(19) United States
(12) Patent Application Publication
(10) Pub. No.: US 2019/0123493 A1
(43) Pub. Date: Apr. 25, 2019

(54) CIRCUIT BOARD CONNECTION DEVICE

(71) Applicant: Weidmüller Interface GmbH & Co. KG, Detmold (DE)

(72) Inventors: Jörg RICHTS, Schlangen (DE); Torsten DIEKMANN, Leopoldshohe (DE); Peter WALKER, Stadhampton (GB)

(21) Appl. No.: 16/167,939

(22) Filed: Oct. 23, 2018

(30) Foreign Application Priority Data
Oct. 24, 2017 (DE) 202017106426.3

(51) Int. Cl. H01R 13/66; H01R 12/52; H05K 1/11

(52) U.S. Cl. CPC H01R 13/6658; H05K 1/115; H01R 12/52

(57) ABSTRACT

An assembly for connecting a cable with a circuit board includes a circuit board and a connecting device. The connecting device has a housing with connecting contacts for connecting conductor ends of a cable wire to the circuit board. The housing is connected to the circuit board by mechanical connectors or latches and by the connecting contacts, each of which extend through a base plate of the housing for conductive connection with contact areas of the circuit board. Thus, the connecting device directly connects the conductor ends of a cable to the circuit board via the connecting device and its single or multi-part contacts.

This application claims priority to German patent application No. 202017106426.3 filed on Oct. 24, 2017. The entire contents of this application is incorporated herein by reference.

### BACKGROUND OF THE DISCLOSURE

The disclosure relates to an assembly having a circuit board connecting device and a circuit board.

German patent No. 20 2006 018 019 U1 discloses a plug connector having two corresponding connector parts, one of which is designed as a male connector part which is adapted to be plugged together with a corresponding female part. The male connector part or the female part may be configured to connect to multi-conductor cables by an insulation-displacement connector (IDC). The '019 patent also discloses a design in which the female part is directly placed into a housing of an electrical appliance—such as a distributor—on a circuit board and connected thereto by soldering. One drawback of this design is that the number of components required for connecting the conductors of the cable to the circuit board is relatively high.

### SUMMARY OF THE DISCLOSURE

Accordingly, it is an object of the present disclosure to provide an assembly including a circuit board and a connecting device for connecting a cable with a circuit board. The connecting device has a housing with connecting contacts for connecting conductor ends of a cable wire to the circuit board. The housing is connected to the circuit board by mechanical connecting devices and by the connecting contacts, each of which extend through a base plate of the housing for conductive connection with contact areas of the circuit board. Thus, the connecting device directly connects the conductor ends of a cable to the circuit board via the connecting device and its single- or multi-part contacts, which removes the need for a plug connection between a male connector part and a female part as discussed above in the prior art.

Preferably, the connecting contacts for connecting the conductor ends are insulation-displacement contacts (IDCs), which provide connection with the contacts without having to strip the conductor ends. Specifically, to create the connection, the conductor ends are placed onto and penetrate into the IDC contacts and the IDC contacts cut through the insulation of the conductor ends to establish an electrical connection with the metal conductor of the conductor ends. The conductor may be a single-wire or a multi-wire/fine-wire conductor. The connection contacts connect with conductive areas of the circuit board via pin contacts located at their lower ends.

The housing further includes a housing base and at least one actuator for connecting the IDC contacts with the ends of the conductor cable. The actuator may be attached to a cover which is slidable and/or pivotable relative to the housing base and may include contours, such as spring latch connectors, that press the conductor ends of a cable into the IDC contacts upon moving the cover. Preferably, the housing includes a locking mechanism for locking the cover to the housing base in a closed position.

In a separate embodiment, the housing has at least one additional connecting contact, for instance a pin contact, for connecting a cable shield with the circuit board. This connecting contact can be a combined cable support and contact device.

A further embodiment includes an assembly having a connecting device as described above but without a circuit board connected thereto.

### BRIEF DESCRIPTION OF THE FIGURES

Other objects and advantages of the disclosure will become apparent from a study of the following specification when viewed in the light of the accompanying drawings, in which:

FIG. 1 is a front perspective view of an assembly having a connecting device and a circuit board with a housing in an open condition without a cable;

FIG. 2 is a perspective view of the assembly of FIG. 1 with a housing in a further opened condition and a cable placed into the housing;

FIG. 3 is a side perspective view of the assembly of FIG. 2 with the housing in an open position;

FIG. 4a is a side perspective view of one embodiment of an assembly with a closed housing;

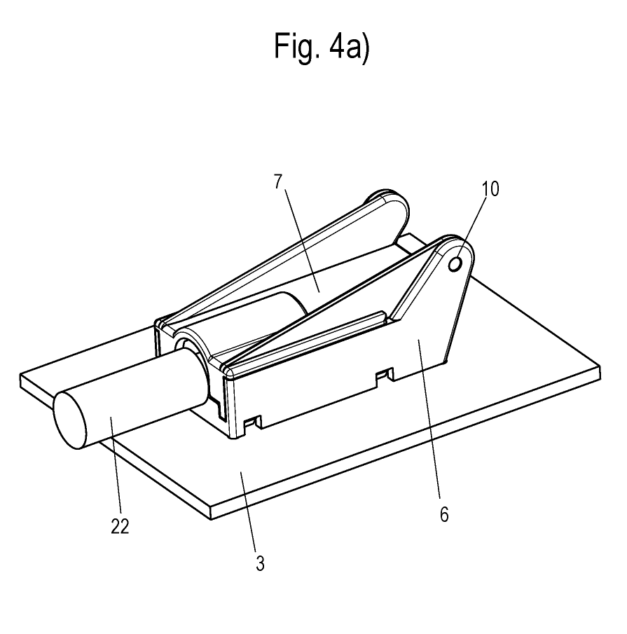

FIG. 4b is a rear perspective view of the embodiment of FIG. 4a; and

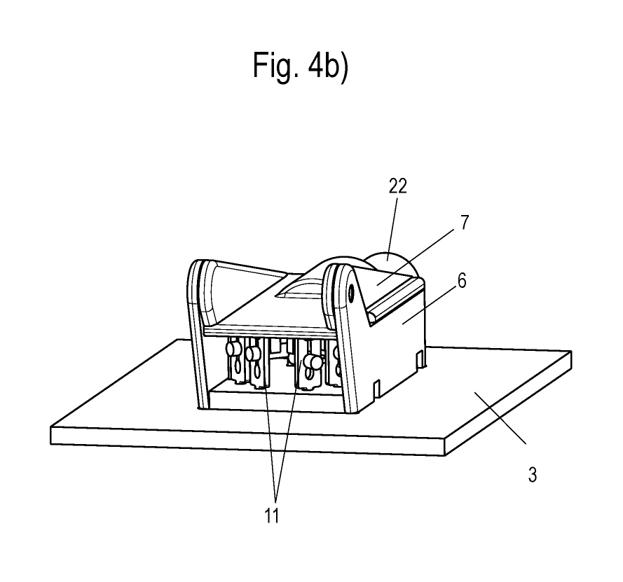

FIG. 5 is a bottom view of one embodiment of the connecting device without a circuit board.

### DETAILED DESCRIPTION

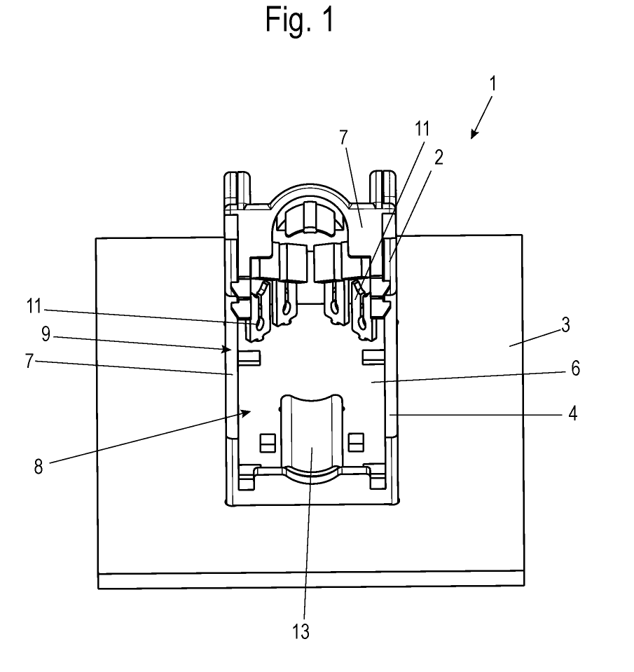

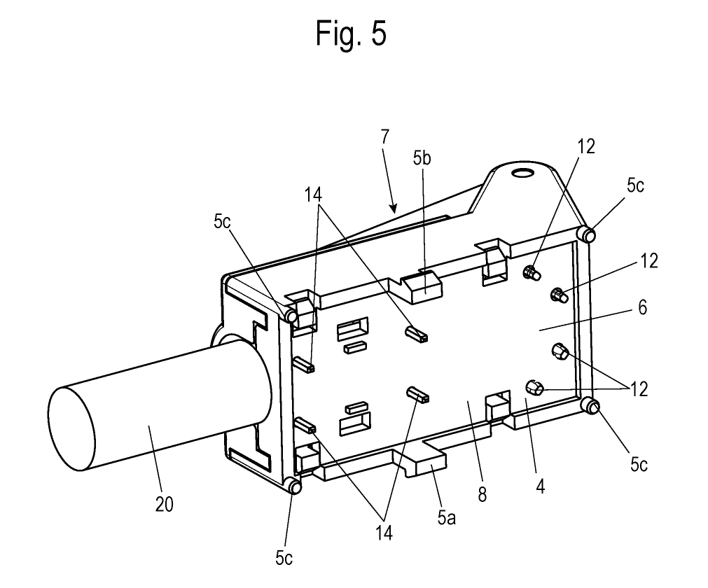

FIG. 1 shows an assembly 1 including a connecting device 2 and a circuit board 3. The connecting device has a housing 4 that is connected with the circuit board 3 via spring latch connectors 5a, 5b, as shown in FIG. 5, which extend through and latch with openings in the circuit board 3. The housing 4 is further connected with the circuit board 3 via pegs 5c which engage corresponding recesses in the circuit board 3, resulting in a non-positive connection. These pegs 5c may also serve as spacers for a circuit board 3 that has no recesses.

Referring again to FIG. 1, the housing 4 has a housing base 6 and a cover 7, and the housing base 6 has a base plate 8 and a frame 9, which, in this instance, are integral with each other. It will be understood by those with skill in the art that rather than providing a base plate and frame that are integral, the two could be fastened to one another.

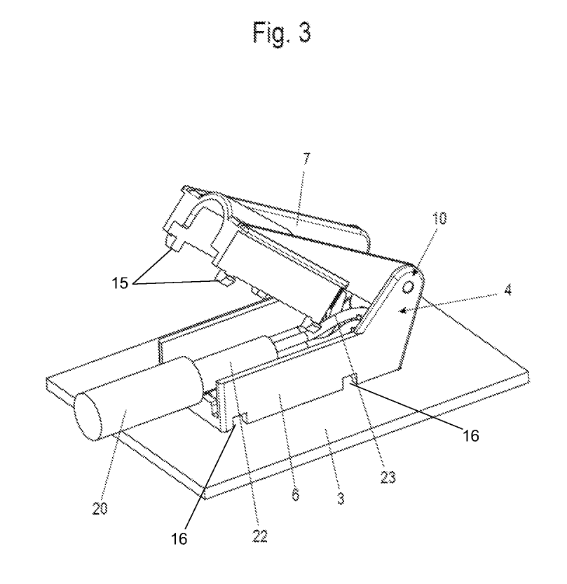

As shown in FIG. 3, the cover 7 is pivotable relative to the housing base 6 via a pivot bearing 10, which permits the housing to pivot between an open position for receiving a cable 20 and a closed position for retaining the cable. In a separate embodiment, the cover 7 is slidable relative to the housing base 6.

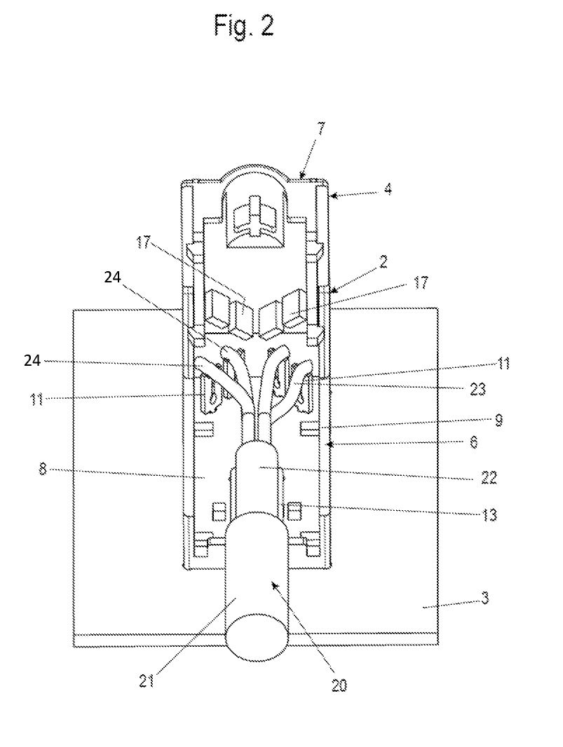

Referring now to FIG. 2, wire conductors 23 are connected with connecting contacts 11, specifically IDC contacts, which create an electrical connection between the cable 20 and circuit board 3. It will be understood that, rather than IDC contacts, the connecting contacts could involve a separate connecting technique, for instance screw connections, spring-cage connections, push-in connections, etc. The IDC contacts 11 here are fork contacts, having one or more sharp edges for cutting conductor insulation. Alternatively, the IDC contacts 11 may be piercing contacts or other types of similar contacts.

As shown in FIG. 5, conductive ends 12 of the IDC contacts extend through openings in the housing base plate 8 for connection with the circuit board 3. Here, the conductive ends 12 are pin contacts. It will be understood by those with skill in the art, that other types of contacts could be used. Further, in a separate embodiment, the conductive ends 12 penetrate through openings in the circuit board 3. In this specific instance, the conductive ends are soldered to the circuit board. Alternative forms of connection are contemplated by this disclosure.

Preferably, housing base 6 and cover 7 are made of an insulating plastic material. In contrast, the connecting contacts 11 and other contacts are preferably made of a metal of good electrical conductivity.

The cable 20 shown in FIG. 2 has a cable jacket 21 or cover, and optionally a cable shield 22, as well as one or more single- or multi-wire conductors 23, each preferably surrounded by an insulation layer. Here, the cable 20 is a round cable, but in separate embodiments it is a ribbon cable. Further, the cable need not have a cable jacket.

The cable 20 is preferably prefabricated for connection by removing a portion of the cable jacket 21 at the cable end as well as a smaller axial portion of the cable shield 22. As such, a part of the cable shield 22 is exposed at its end and the conductor ends 24 in turn freely protrude axially therefrom. The insulation of the conductor ends does not have to be removed.

Referring again to FIG. 1, a contact socket 13 arranged at the housing base 8, onto which the stripped cable is placed, provides a conductive connection of the cable shield 22 with the circuit board 3. The contact socket can alternatively be connected with the circuit board via one or more connecting contacts 14 or It can be integral therewith. It is preferably made of a conductive material, in particular a metal of good electrical conductivity. If a connecting contact is included, it is preferably a pin contact, and is guided through the base plate 8 for connection with the circuit board 3.

The housing base 6 is preferably retained on the circuit board 3 by IDC contacts 11 and is also directly mechanically connected by positive and/or non-positive connecting mechanisms, for instance the aforementioned spring latch connectors 5a, 5b and/or pegs 5c. Thus, in an exemplary embodiment, the frame 9 is connected with the circuit board 3 by a positive and/or non-positive connection.

As shown in FIG. 3, the cover 7 includes a latching mechanism 15, by which it is releasably attachable with the housing base 6 via mating latching openings 16, for securing the cover in its closed position.

The assembly described above results in the housing 4 being directly mechanically connected with the circuit board 3 and the connecting contacts and the cable shield being conductively connected with the circuit board 3. Thus, a plug connection between a male connector and a female connector, which is disclosed in the prior art, is no longer necessary. Instead, the cable conductor ends 24 are connected with the circuit board 3 via the connecting device.

As is discussed above, each conductor 23 is connected by connecting contacts 11. However, in a separate embodiment, two IDC contacts per conductor may be included to optimize the electrical contact between the cable and the circuit board.

Connection of the IDC contact is performed by an actuator, which in this case is a cover 7. It connects the wire conductors 23 to the IDC contacts via projections 17, which press the conductors 23 into one or more IDC contacts upon closing the cover 7, in turn cutting the insulation of the conductor ends 24 permitting the inner conductor to contact the IDC contacts.

In a preferred embodiment, to effectuate the connection between the cable and circuit board, the connecting device 2 is first pre-mounted via latch spring connectors 5a, 5b with the circuit board 3 and the contact pins 12, 14 are conductively connected with the circuit board 3. Then, a prefabricated cable 20 is inserted into the housing for connection of its conductors with the contact connectors. If the cable has a shield 22, it is removed or opened and folded back and placed onto the connecting and contact socket 13 for connecting the conductor shield. The conductors 23 and cable shield 22 are exposed down to their insulation and are each placed onto corresponding IDC contacts 11. The cover 7 is then closed causing the latching mechanism 15 to be pressed onto the conductor ends 24 which are forced into the IDC contacts 11 such that they cut the insulation of the wire and contact the conductors. The cover 7 connects with the housing base 6, fixing the cable shield to the support 13. Thus, the conductors 23 of cable 20, and, optionally, those of the cable shield 22, are easily connected with the circuit board 3 using very few elements.

Although the above description with reference to particular embodiments, it is to be understood that these embodiments are merely illustrative of the principles and applications of the present disclosure. It is therefore to be understood that numerous modifications may be made to the illustrative embodiments and that other arrangements may be devised and employed without departing from the spirit and scope of the present disclosure.

1-13. (canceled)

14. A connector assembly, comprising:
(a) a circuit board including at least one conductive contact area; and
(b) a connecting device including:
(1) a housing including a base mechanically connected with said circuit board, said base containing at least one opening therein; and
(2) at least one connecting contact arranged within said housing and extending through said base opening, said at least one connecting contact being electrically connected with said conductive contact area of said circuit board and being configured to receive conductor ends of a cable.

15. An assembly as defined in claim 14, wherein said housing includes a cover moveable relative to said base.

16. An assembly as defined in claim 15, wherein said cover is moveable in one of a slidable and pivotable direction relative to said housing base.

17. An assembly as defined in claim 14, wherein said at least one connecting contact comprises an insulation-displacement contact.

18. An assembly as defined in claim 14, wherein said at least one connecting contact comprises a pin contact conductively connected to said conductive contact areas of said circuit board.

19. An assembly as defined in claim 17, wherein said housing further includes an actuating element for connecting a wire with said at least one insulation-displacement contact.

20. An assembly as defined in claim 19, wherein said actuating element includes projections extending from an inner surface of said cover for pressing an end of a cable into said at least one insulation-displacement contact.

21. An assembly as defined in claim 20, wherein said cover further includes at least one latching mechanism for locking said cover with said housing base in a closed position.

22. An assembly as defined in claim 14, wherein said connecting device further has at least one shield connecting contact for connecting a cable shield of a cable with said connecting device.

23. An assembly as defined in claim 22, wherein said shield connecting contact includes a pin contact conductively connected to said one conductive contact area of said circuit board.

24. An assembly as defined in claim 23, wherein said shield connecting contact is a combined cable support and contact device.

25. An assembly as defined in claim 14, wherein said housing is mechanically connected with said circuit board via one of a positive and non-positive connection.

26. A connecting device comprising:
(a) a housing including a base mechanically connectable with a circuit board and a cover moveable relative to said base including at least one latching mechanism for locking said cover with said base, said base containing at least one opening therein; and
(b) at least one connecting contact arranged within said housing and extending through said base opening, said at least one connecting contact being electrically connectable with a conductive contact area of a circuit board and being configured to receive conductor ends of a cable.
